(19) United States
(12) Patent Application Publication
(10) Pub. No.: US 2007/0238270 A1
(43) Pub. Date: Oct. 11, 2007

(54) Method for forming polycrystalline film

(75) Inventors: Eok Su Kim, Seoul (KR); Myung Kwan Ryu, Kyoungki-do (KR); Gon Son, Kyoungki-do (KR); Hyuk Soon Kwon, Kyoungki-do (KR); Jung Ho Park, Seoul (KR)

Correspondence Address: SEYFARTH SHAW LLP, 131 S. DEARBORN ST., SUITE2400, CHICAGO, IL, 60603-5803, US

(73) Assignee: Boe Hydis Technology Co., Ltd.

(21) Appl. No.: 11/731,983

(22) Filed: Apr. 2, 2007

(30) Foreign Application Priority Data
Apr. 6, 2006 (KR) 10-2006-0031565

(51) Int. Cl. H01L 21/20

(52) U.S. Cl. 438/487; 257/E21.134

(57) ABSTRACT

Disclosed is a method for forming a polycrystalline film. The method for forming a polycrystalline film from a film deposited on a glass substrate while a buffer layer is interposed between the deposited film and the glass substrate, which includes the steps of: preparing a mask including a transparent region having a larger size than that of resolution limitation of a laser beam equipment and an opaque region having a size which is smaller than that of the resolution limitation of the laser beam equipment; and irradiating laser beam of the maximum intensity to a film under the transparent region while irradiating the laser beam having a minimum intensity exceeding zero to the film under an opaque region by using the mask, thereby crystallizing the film by single irradiation of the laser beam.

### BACKGROUND OF THE INVENTION

1. Field of the invention

The present invention relates to a method for forming a polycrystalline film, and more particularly to a method for forming polycrystalline silicon film in order to form polycrystalline silicon transistors.

2. Description of the Prior Art

Thin Film Transistors (hereinafter, referred to as TFT), which are used as switching elements in liquid crystal displays or organic Electro Luminescence displays, are very important structural elements in an aspect of performance of flat panel display. Herein, mobility or leakage current, etc., which is used as a reference for determining the performance of TFT, is greatly influenced by a status or a structure of active layer which is a pathway through which charge carriers move, i.e. by a status or a structure of silicon thin film which is material for the active layer. Currently, in the case of commercially available liquid crystal display, the active layer of the TFT is mostly made of amorphous silicon (hereinafter, referred to as a-Si).

Meanwhile, since an a-Si TFT in which the a-Si is used as the active layer has a significantly low mobility of about 0.5 cm²/Vs, it is restrictive that all switching elements used for the liquid crystal displays are made of the a-Si TFT. Specifically, although driving elements for peripheral circuits of the liquid crystal displays are operated at a rapid velocity, the a-Si TFT cannot satisfy operation velocity required in the driving elements for the peripheral circuits. Therefore, this means that it becomes eventually difficult to realize the driving elements for the peripheral circuits using the a-Si TFT.

On the other hand, poly-Si TFT in which polycrystalline silicon (hereinafter, referred to as poly-Si) is used as an active layer has a high mobility of about several tens of times˜several hundreds of times cm²/Vs, so as to operate at a high velocity corresponding to driving elements for peripheral circuits. Therefore, when a poly-Si film is formed on a glass substrate, not only pixel switching elements but also the driving elements for the peripheral circuits can be realized. Thus, not only is a separate module process unnecessary for forming the peripheral circuits, but also the peripheral circuit driving elements are formed along with a pixel region, thereby reducing the cost of the driving parts for peripheral circuits.

Further, as having the high mobility, the poly-Si TFT can be made to be smaller than the a-Si TFT. Furthermore, since the driving elements in the peripheral circuit and the switching elements in pixel region can be simultaneously formed by an integration process, a line-width can be easily narrowed so that high resolution which is difficult to be realized in the a-Si TFT-LCD is easily obtained.

In addition, as the poly-Si TFT has high current characteristics, it is suitable for a driving element of an organic Electro Luminescence display used as an advanced flat panel display. Recently, there has been actively progressed the research for the poly-Si TFT which is manufactured by forming poly-Si film on a glass substrate.

Here, in a method for forming the poly-Si film on the glass substrate, an a-Si film is deposited and then heat-treated so as to crystallize the a-Si film. In this case, the glass substrate is deformed at temperatures higher than 600° C., thereby causing a reduction in reliability and yield.

Therefore, an Excimer Laser Annealing (hereinafter, referred to as ELA) method has been proposed as a method for crystallizing only the a-Si film without causing thermal damage to the glass substrate. Further, a Sequential Lateral Solidification (hereinafter, referred to as SLS) method has been proposed.

However, according to the ELA method, a laser beam is irradiated to the a-Si film so as to obtain the poly-Si film. The a-Si film is not completely but partially melted, so that the crystalline grains of the poly-Si film have a small and uneven size so as to deteriorate the characteristics and uniformity of the poly-Si TFT. Further, in the ELA method, since the laser beam is repeatedly irradiated in order to improve the uniformity of the characteristics of the poly-Si TFT, the productivity of the poly-Si TFT is lowered, and the process window becomes small.

On the other hand, according to the SLS method, a pulse laser beam is irradiated to the a-Si film through a mask having slit patterns for selectively providing a transparent portion in a shot or scanning manner. Si crystal is grown at a boundary between the liquid portion which is fully exposed to the irradiated laser beam, and melted, and the solid portion which is not exposed to the irradiated laser beam. Therefore, the SLS method can form the poly-Si film having larger crystal grains than those in the ELA method.

Specifically, the conventional SLS method is performed by using a mask M including a transparent region 1 having a slit pattern and an opaque region 2, as shown in FIG. 1. According to the conventional SLS method, a laser beam is transmitted through the transparent region 1, but cannot be transmitted through the opaque region 2. Thus, the a-Si portion is melted by the laser beam transmitted through the transparent region 1. As time passes, Si crystals are grown from a lateral side of the melted a-Si.

FIG. 2 shows a spatial intensity profile of the laser beam passing through a region marked by a line A-A′ in FIG. 1. As shown in FIG. 2, the spatial intensity of the laser beam is maximized in the transparent region, while becoming zero in the opaque region.

However, in the case of the SLS method, as the regions to which the laser beam is irradiated and the regions to which the laser beam is not irradiated are alternately arranged, at least two irradiations of the laser beam are required for crystallizing whole a-Si film. Thus, this causes the deterioration of productivity. Further, as the poly-Si has a size of crystal grain which is different between the portion in which the laser beam overlaps and the portion in which the laser beam does not overlap, there exists a problem in that the characteristics of the poly-Si TFT is deteriorated.

Furthermore, according to the SLS method, a high angle grain boundary is formed at a collision point which Si crystal grains growing from the boundaries between the solid portion and the liquid portion meet. However, controlling of the position of the high angle grain boundary is difficult, so that the characteristics of the poly-Si TFT become deteriorated.

### SUMMARY OF THE INVENTION

Accordingly, the present invention has been developed in order to solve the above-mentioned problems occurring in the prior art, and an object of the present invention is to provide a method for forming polycrystalline film, which can prevent the deterioration of the productivity which is caused by the laser beam irradiated several times.

Another object of the present invention is to provide a method for forming polycrystalline film, which can prevent the deterioration of the characteristics and the uniformity of poly-Si TFT which is caused by an uneven size of crystal grains and uneven forming of high angle grain boundary.

In order to accomplish the objects of the present invention, there is provided a method for forming a polycrystalline film from a film deposited on a glass substrate while a buffer layer is interposed between the deposited film and the glass substrate, which comprises the steps of: preparing a mask including a transparent region having a larger size than that of resolution limitation of a laser beam equipment and an opaque region having a size which is smaller than that of the resolution limitation of the laser beam equipment; and irradiating laser beam of the maximum intensity to a film under the transparent region while irradiating the laser beam having a minimum intensity exceeding zero to the film under an opaque region by using the mask, thereby crystallizing the film by single irradiation of the laser beam.

The opaque region includes line type patterns or dot type patterns.

The dot type patterns are circle or polygonal.

The dot type patterns are regularly arranged at a center portion in each sector of a checkerboard pattern, or are regularly arranged in zigzags.

The line type patterns or the dot type patterns have regular inter-pattern distances, irregular inter-pattern distances, or complex inter-pattern distances including regular and irregular inter-pattern distances.

The transparent region has a size enough to prevent creation of nucleation.

The laser beam has intensity enough to completely melt a portion of a film under the transparent region, to partially melt another portion of the film under the opaque region, so as to form polycrystalline seed in the partially melted portion of the film. Further, the laser beam has intensity enough to completely melt a portion of a film under the transparent region, and to near completely melt another portion of the film under the opaque region, so that a single crystal seed remains in the near completely melted portion of the film. Furthermore, the laser beam has enough intensity to completely melt a portion of the film under the transparent region, and to completely melt another portion of the film under the opaque region.

The film is any one film selected from a group of films, made of third group element, fifth group element, and their compound, which include an a-Si film, a poly-Si film, an a-Ge film, a poly-Ge film, an a-SiₓGe_{y} film, a poly-SiₓGe_{y} film, an a-GaNₓ film, a poly-GaNₓ film, an a-GaₓAs_{y} film, and a poly-GaₓAs_{y} film.

The film is a metal film, or a compound film of metal and semiconductor. At this time, the metal film is any one film selected from a group of an Al film, a Cu film, a Ti film, a W film, an Au film, and a Ni film.

### BRIEF DESCRIPTION OF THE DRAWINGS

The above and other objects, features, and advantages of the present invention will be more apparent from the following detailed description taken in conjunction with the accompanying drawings, in which:

FIG. 1 is a view illustrating a mask formed using a method of forming polycrystalline film according to a conventional Sequential Lateral Solidification (SLS);

FIG. 2 is a graph showing a spatial intensity profile of laser beam passing through a line A-A′ in FIG. 1;

FIG. 3 is a view illustrating a method of forming polycrystalline film according to the present invention;

FIGS. 4A to 4C are plane views showing masks used for the present invention, and illustrating shapes of crystal grains corresponding to the masks, respectively;

FIG. 5 is a view showing crystallization according to energy density of a laser beam;

i5 FIG. 6 is a photograph of poly-Si film formed according to an embodiment of the present invention; and

FIGS. 7A to 7E are views illustrating various crystallizations according to the present invention.

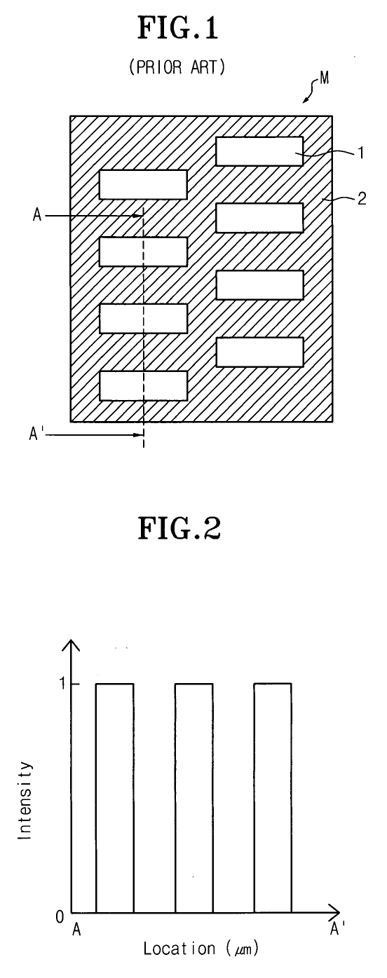

### DETAILED DESCRIPTION OF THE PREFERRED EMBODIMENTS

Hereinafter, the preferred embodiment of the present invention will be described with reference to the accompanying drawings.

First, the technical principle of the present invention will be described in brief. The present invention presents a method for forming a poly-Si film, in which a laser beam is irradiated to a-Si film, which is deposited on a glass substrate in a state that a buffer layer is interposed between the a-Si film and the glass substrate, by using a mask, so as to crystallize the a-Si film. At this time, the laser beam is irradiated at maximum intensity to a portion of the a-Si film under a transparent region of the mask while being irradiated at minimum intensity exceeding zero to another portion of the a-Si film under an opaque region of the mask, by using the mask including a larger transparent region than a limitation size of the resolution of a laser beam equipment and a smaller opaque region than a limitation size of the resolution of the laser beam equipment.

In this case, the portion of the a-Si film under the transparent region is completely melted, while another portion of the a-Si film under the opaque region is partially melted, near completely melted, or completely melted. When the a-Si film under the opaque region is partially melted, the polycrystalline seed is formed in the bottom of film, and the crystallization proceeds from the seed so as to form the poly-Si film. When the a-Si film under the opaque region is near completely melted, the single crystalline seed remains in the bottom of film, and the crystallization proceeds from the seed so as to form the poly-Si film. In a case where the a-Si film under the opaque region is completely melted, when the melted Si is cooled, the melted Si under the opaque region has a temperature which is lower than that of the melted Si under the transparent region, so that seed is formed in the melted Si under the opaque region. Then, the crystallization proceeds from the seed so as to form the poly-Si film. At this time, no seed is formed in the melted Si under the transparent region.

In making a comparison between the present invention and the conventional art, according to the conventional SLS method, the crystallization starts in a boundary area between the liquid portion in which the a-Si film is completely melted and the solid portion in which the a-Si film is not melted at all. On the contrary, according to the present invention, a seed for crystallization is formed in the specific portion of the a-Si film and the remaining portion of the a-Si film excluding the portion in which the seed is formed, is completely melted so that the crystallization from the seed is performed. Therefore, in the conventional SLS method, the irradiation of the second laser beam is required after the first laser beam is irradiated. However, in the method of the present invention, the single irradiation of the laser beam makes it possible to crystallize whole region of the a-Si film.

As described above, in the present invention, the single irradiation of the laser beam enables the remaining portion excluding the seed forming region to be melted so as to form the poly-Si film from the seed. Thus, an additional irradiation of the laser beam is not required.

Therefore, the present invention can improve the productivity more than that of the conventional ELA or SLS method. Further, the repeated laser beam irradiation and the laser beam overlap do not cause the non-uniformity of the characteristics, so that the characteristics of the product can be improved.

Furthermore, according to the present invention, the distance and size of the opaque region can be adjusted so as to easily control the size and position of the crystal grains. Thus, the distance between the opaque regions can be even so as to form the poly-Si film having even sized crystal grains. As a result, the present invention can improve the characteristics and uniformity of the poly-Si film as compared with the conventional ELA or SLS method.

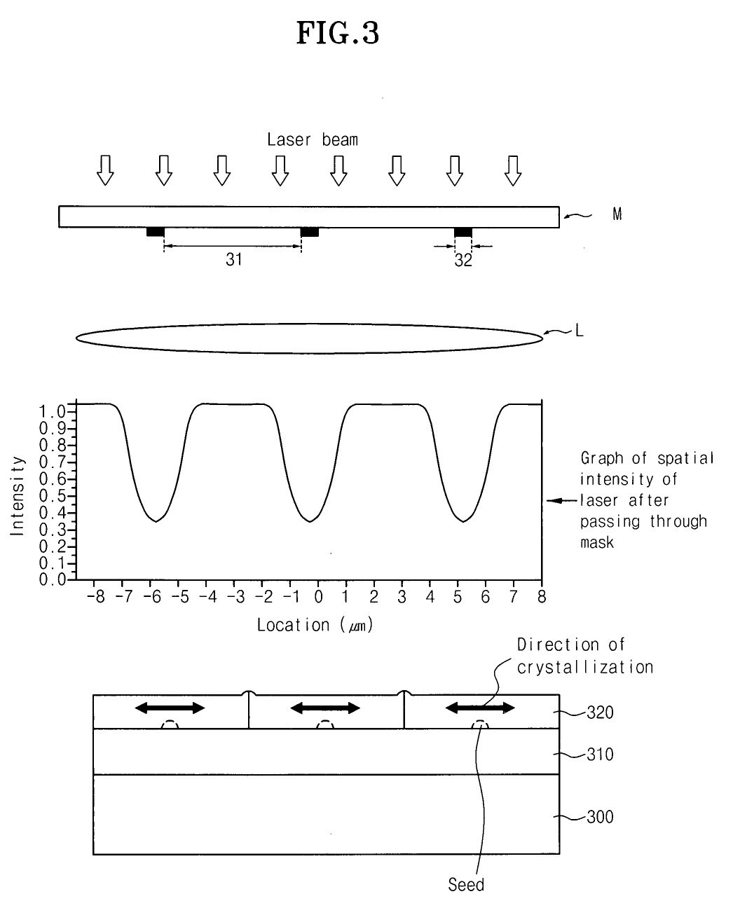

Specifically, FIG. 3 is a view illustrating a method for forming the poly-Si film according to the present invention. Hereinafter, the method will be described.

FIG. 3 shows a mask M used in the present invention and a graph of spatial intensity profile of a laser beam passing through the mask M, and illustrates a process for forming seeds and poly-Si film from the a-Si film by irradiating the laser beam through the mask M.

Referring to FIG. 3, as described above, the laser beam is irradiated at maximum intensity to a portion of the a-Si film under a transparent region 31 of the mask, while being irradiated at minimum intensity exceeding zero to another portion of the a-Si film 320 under an opaque region 32 of the mask M, by using the mask M including the transparent region 31 which is larger than a limitation size of the resolution of a laser beam equipment and the opaque region 32 which is smaller than the limitation size of the resolution of the laser beam equipment. In this case, the a-Si film 320 under the transparent region 31 is completely melted while the a-Si film 320 under the opaque region 32 is partially melted, near completely melted, or completely melted, so that the seed is crystallized so as to form the poly-Si film from the seed.

A lens L is located in a space between the mask M and the a-Si film 320, but a proximity type equipment without the lens L may be used. Reference numerals 300 and 310, which are not described, indicate a glass substrate and a buffer layer, respectively.

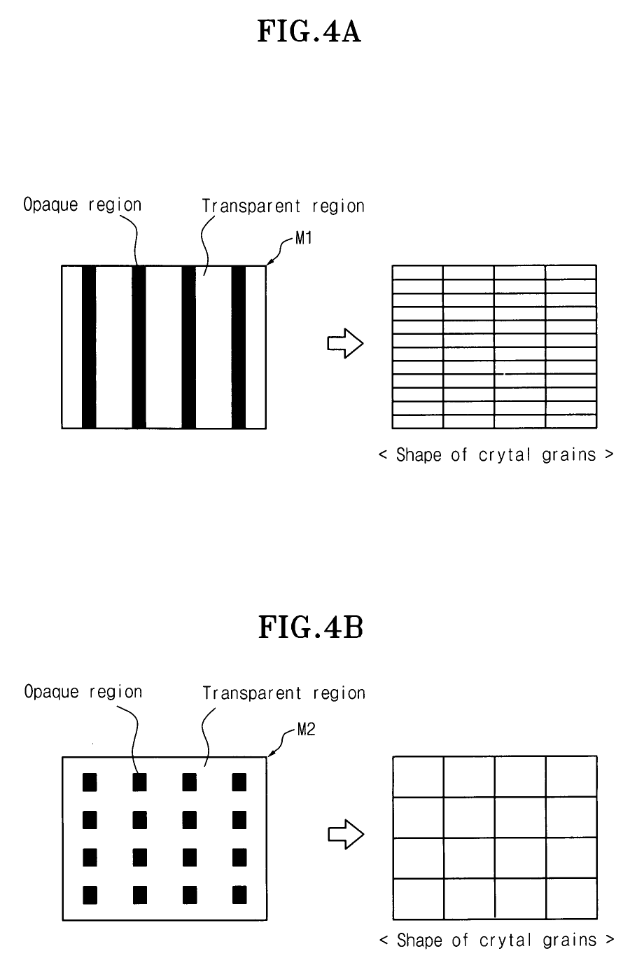

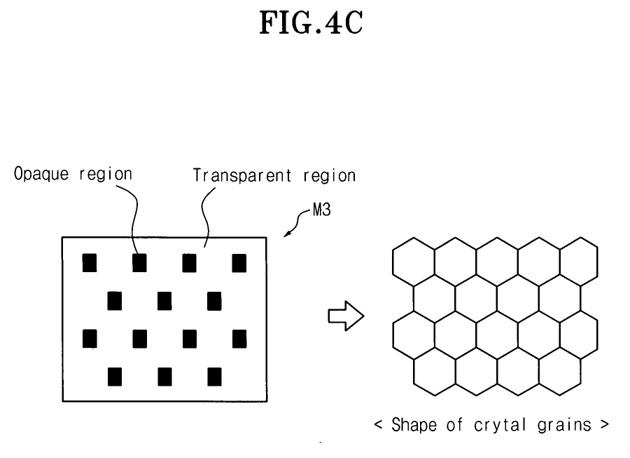

Herein, the mask M has various shapes. Hereinafter, the mask M having various shapes which can be used for the present invention, and the size of the crystal grain corresponding to the mask will be described with reference to FIGS. 4A to 4C.

FIG. 4A shows a first mask Ml having a line type opaque region with an identical distance, and the shape of the crystal grain corresponding to the mask Ml. Referring to FIG. 14A, when the crystallization is performed by using the first mask M1, it is possible to form the poly-Si film having a rectangular shaped crystal grain.

FIG. 4B shows a second mask M2 in which the opaque region is formed with a dot type pattern arranged at a center portion of each sector in the checkerboard shaped mask M2, and the shape of the crystal grain corresponding to the mask M2. Referring to FIG. 4B, when the crystallization is performed by using the second mask M2, it is possible to evenly form the poly-Si film having a square shaped crystal grain.

FIG. 4C shows a third mask M3 in which the opaque region is formed with dot type patterns regularly arranged in zigzags, in which the shape of the crystal grain corresponds to the mask M3. Referring to FIG. 4C, when the crystallization is performed by using the third mask M3, it is possible to form the poly-Si film having a hexagonal shape.

Although not shown, the dot type pattern may have not only a square shape but also a polygonal shape or a circular shape. Further, the line type patterns or the dot type patterns may have regular inter-pattern distances, irregular inter-pattern distances, or complex inter-pattern distances including regular and irregular inter-pattern distances.

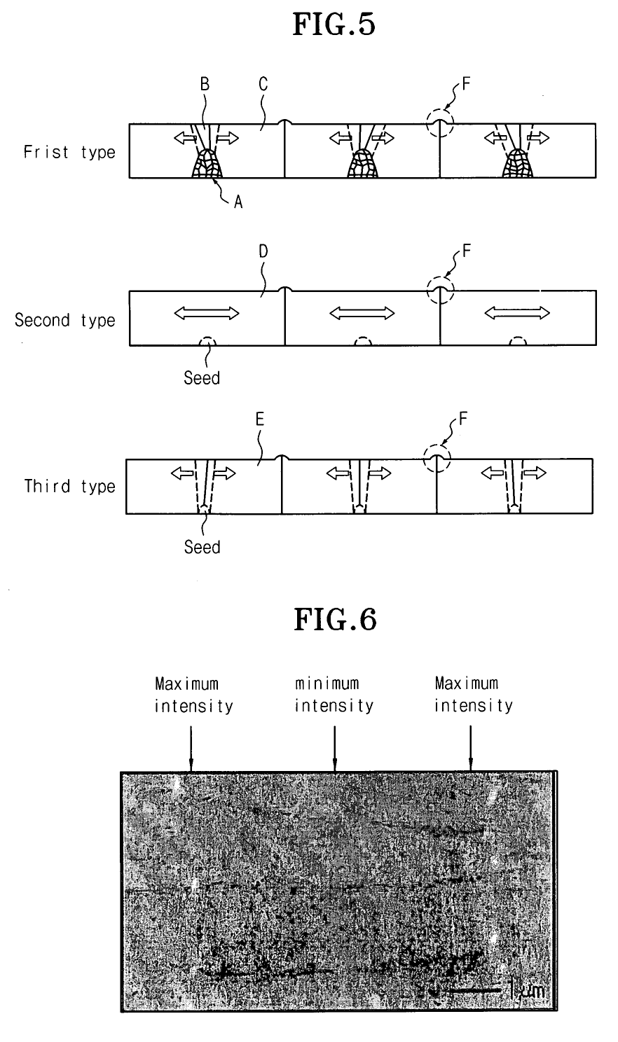

FIG. 5 is a view showing crystallization according to the energy density of the laser beam. Referring to FIG. 5, in the case of a first type crystallization having the laser beam of the lower energy density, the a-Si film under the opaque region of minimum intensity is partially melted and the a-Si film under the transparent region of maximum intensity is completely melted.

In this case, after the laser beam is irradiated, heat is transferred from the partially melted Si to the lower solid a-Si film, so that a solid a-Si film is melted and again solidified while being crystallized. Thus, the a-Si film is converted into the first Si film A formed with a plurality of fine crystal grain.

On the other hand, while the first Si film A is formed, the grains vertically grow at an upper end of the first Si film A, so as to form the second Si film B having small sized grains.

Next, some grains laterally grow from a side of the second Si film B, so as to form the third Si film C having large sized grains. Here, the reason that the vertical growth is firstly performed rather than the lateral growth is because the portion of the Si film under the opaque region of minimum intensity has a low temperature, so as to be primarily crystallized.

Meanwhile, in the case of the second type crystallization using a laser beam of higher energy density than that of the first type crystallization, the a-Si film under the opaque region of minimum intensity is near completely melted and the a-Si film under the transparent region of maximum intensity is completely melted and the single crystal seed having a very small size remains. Then, the crystallization is performed at all lateral sides of the seed, so as to form the fourth Si film D having a very large grain size. Here, reference numeral F indicates protrusions formed by collision between the growing crystal grains. The growing crystal grains form the protrusions F having a high angle grain boundary and then their growth stops.

In the case of a third type crystallization using a laser beam of higher energy density than that of the second type crystallization, the entire a-Si film including a portion of the a-Si film under the opaque region of minimum intensity is completely melted. While the completely melted a-Si film is slowly cooled, seed having plural crystal grains are formed at the portion of the liquid Si under the opaque region of minimum intensity because the portion of the liquid Si has the lowest temperature. Then, the crystallization is performed in the polycrystalline seed, so as to form the fifth Si film E having a smaller crystal grain than that of the fourth Si film D. At this time, the reason for forming the polycrystalline seed in the third type crystallization is that while the a-Si film is completely melted and cooled again, the cooling velocity is too rapid to make the seed grow in a single crystal film. However, if the cooling velocity is allowed to be slow so as to form a single crystal seed after the a-Si film is melted, it is possible to obtain single crystal grains which are as large as that of the fourth Si film D.

Here, the energy density corresponding to the first, second and third type crystallizations are changed according to the processing condition and the thickness of the a-Si film. Therefore, it is impossible to limit the range of the energy density corresponding to each crystallization type to a certain value.

Among the first, second and third type crystallizations, the second type crystallization can obtain the poly-Si film having the largest crystal grain. This type crystallization is suitable for achieving the object of the present invention. FIG. 6 is a photograph showing the poly-Si film formed by using the laser beam having the energy density which can satisfy the second type crystallization. Referring to FIG. 6, the single crystal Si film grows from the opaque region of minimum intensity and then its growth stops while forming the protrusions in the transparent region of maximum intensity, thereby forming the poly-Si film including the crystal grains with the relatively uniform and large size.

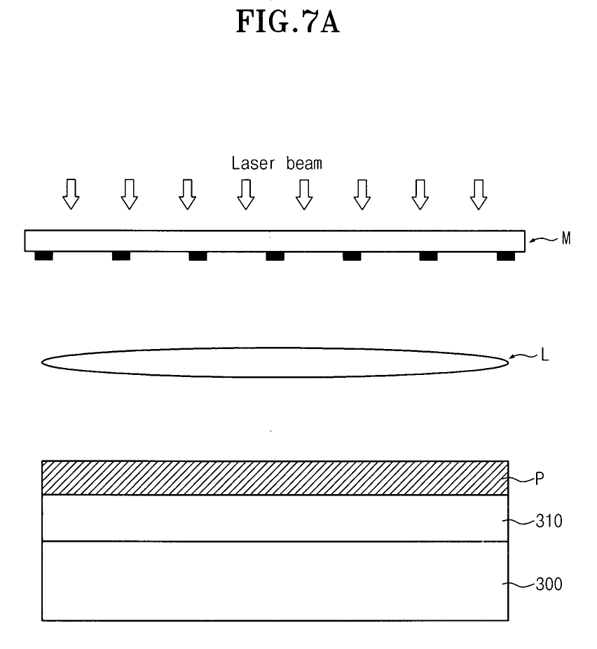

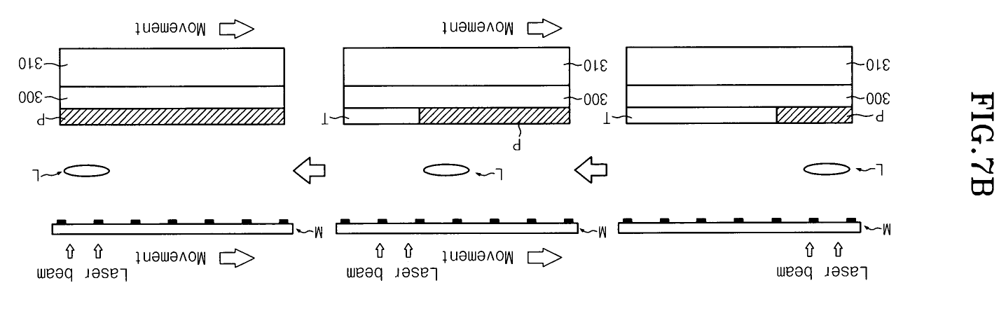

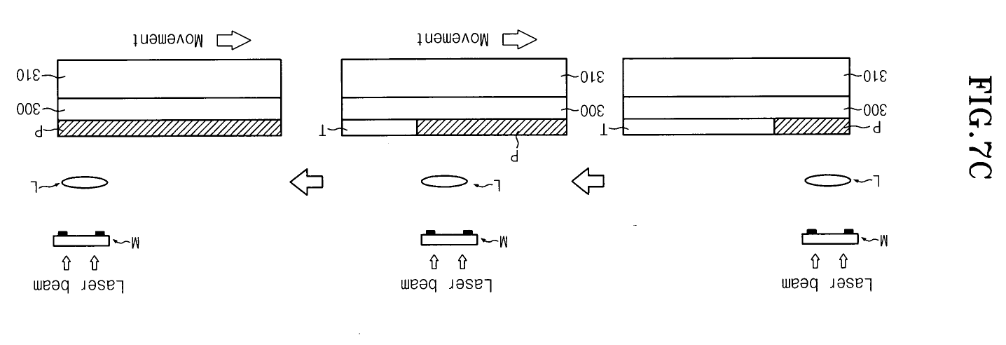

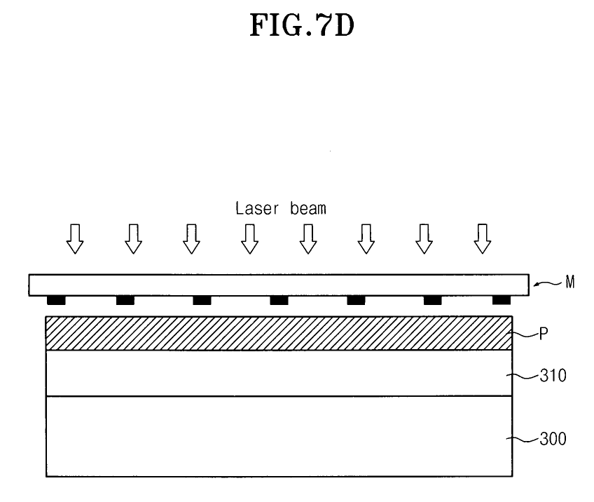

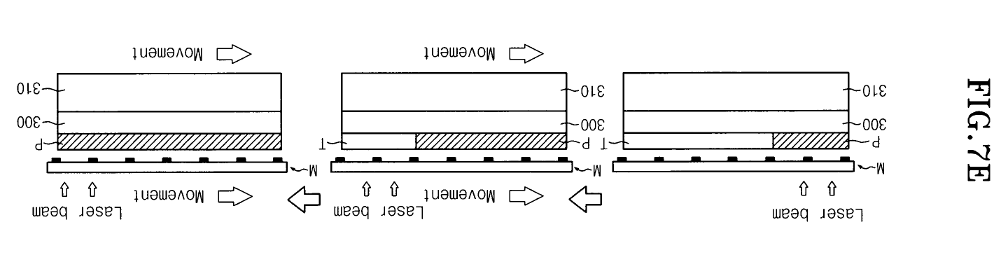

On the other hand, the present invention can be variously embodied based on the kind of equipment, and the size of the mask and glass substrate. Hereinafter, various crystallization method will be described with reference to FIGS. 7A to 7E.

As shown in FIGS. 7A to 7C, a lens L is used in the present invention. The resolution of the equipment is the same as the following formula (1):

That is, resolution=0.5*λ/NA formula (1),

wherein λ is a wavelength, and NA is a Numerical Aperture.

In FIG. 7A, the laser beam may be irradiated to the entire glass substrate 300 at one time. In addition, the lens L is large enough to cover the entire glass substrate 300. In this case, the entire region of the film T which is formed on the glass substrate 300 is crystallized by one irradiation of the laser beam so as to form the crystallized film P.

In FIGS. 7B and 7C, the laser beam cannot be irradiated to the entire glass substrate 300 at one time. In addition, the lens L is smaller than the glass substrate 300. In FIG. 7B, the single irradiation process is repeatedly performed while the mask M and the glass substrate 300 are simultaneously moved in the same direction, thereby crystallizing the entire region of the film T. In FIG. 7C, the single irradiation process is repeatedly performed while only the glass substrate 300 is moved, thereby crystallizing the entire region of the film T.

In FIGS. 7D and 7E, on the other hand, the proximity type equipment having no lens is used. In this case, the mask M is in contact with, or stays adjacent to the film T to be crystallized. The resolution of the equipment is represented by the following formula (2):

That is, resolution=(λZ/2)^{1/2} formula (2),

wherein Z is a distance between the mask M and the substrate.

In FIG. 7D, the laser beam may be irradiated to the entire glass substrate 300 at one time. In this case, the entire region of the film T formed on the glass substrate 300 can be crystallized by one irradiation of the laser beam.

In FIG. 7E, the laser beam cannot be irradiated to the entire glass substrate 300 at one time. In this case, the single irradiation process is repeatedly performed so as to crystallize the entire region of the film T while the mask M and the glass substrate 300 are simultaneously and horizontally moved by a desired distance. In FIGS. 7A to 7E, reference numeral 310 as not described above indicates a buffer layer.

As described above, by using the mask which includes a transparent region having a larger size than that of resolution limitation of the laser beam equipment and an opaque region having a smaller size than that of the resolution region of the laser beam equipment, the laser beam of the maximum intensity is irradiated to the film under the transparent region while the laser beam of the minimum intensity exceeding zero is irradiated to the film under the opaque region, so that the crystal seed is formed at the opaque region of minimum intensity and crystallization is performed from the seed. As a result, it is possible to form the polycrystalline film having large crystal grains through the single irradiation of the laser beam.

Therefore, according to the present invention, it is possible to prevent the non-uniformity of the characteristics due to laser beam overlap, and the deterioration of the productivity due to the repeat irradiation of the laser beam to the same region according to the conventional ELA or SLS.

Further, the present invention can adjust the distance and the size of the opaque region, so as to easily control the size and the location of the crystal grains. Furthermore, the distance between the opaque regions can be even so as to form the polycrystalline film having even sized crystal grain, thereby improving the characteristics and the uniformity of the polycrystalline film in comparison with the conventional ELA or SLS method.

On the other hand, although the embodiment of the present invention is shown and described with relation to the a-Si film used for the crystallization, the method of the present invention can be applied to, instead of a-Si film, films made of another material, for example any one film selected from a group of films made of third group element, fifth group element and their compound including poly-Si film, a-Ge film, poly-Ge film, a-SiₓGe_{y} film, poly-SiₓGe_{y} film, a-GaNₓ film, poly-GaNₓ film, a-GaₓAs_{y} film, and poly-GaₓAs_{y} film. Further, the present invention may also be applied to metal film such as Al film, Cu film, Ti film, W film, Au film, and Ni film, or the compound of the metal film and semiconductor. Here, in the case where the polycrystalline film, for example poly-Si film, etc., is used as the crystallized film, the size of the crystal grain increases and becomes uniform.

As described above, the present invention can melt the remaining region of the crystallized film excluding the region for forming crystal seed by once irradiation of the laser beam, by using the mask including the transparent region larger than the resolution limitation of the laser beam equipment, and the opaque region smaller than the resolution limitation of the laser beam equipment, so as to crystallize the seed in order to form the polycrystalline film. Thus, in comparison with the conventional ELA or SLS method, it is possible to prevent the deterioration of the productivity resulting from the repeat irradiation of the laser beam. As a result, the present invention can greatly improve productivity in comparison with the conventional ELA or SLS method.

Furthermore, the present invention can not only prevent the non-uniformity of the characteristics of the polycrystalline film which result due to the overlapping of the laser beam, but also can easily adjust the distance and size of the opaque region so as to control the size and the location of the crystal grain. In addition, the present invention can enable the distance between the opaque region to be even so as to form the polycrystalline film having the crystal grain with even size, thereby improving the characteristic and the uniformity of the polycrystalline film in comparison with the conventional ELA or SLS method.

While a preferred embodiment of the present invention has been described for illustrative purposes, those skilled in the art will appreciate that various modifications, additions and substitutions are possible, without departing from the scope and spirit of the invention as disclosed in the accompanying claims.

What is claimed is:

1. A method for forming a polycrystalline film from a film deposited on a glass substrate while a buffer layer is interposed between the deposited film and the glass substrate, the method comprising the steps of:
preparing a mask including a transparent region having a larger size than that of resolution limitation of a laser beam equipment and an opaque region having a size which is smaller than that of the resolution limitation of the laser beam equipment; and
irradiating laser beam of the maximum intensity to a film under the transparent region while irradiating the laser beam having a minimum intensity exceeding zero to the film under an opaque region by using the mask, thereby crystallizing the film by single irradiation of the laser beam.

2. The method as claimed in claim 1, wherein the opaque region includes line type patterns or dot type patterns.

3. The method as claimed in claim 2, wherein the dot type patterns are circle or polygonal.

4. The method as claimed in claim 2, wherein the dot type patterns are regularly arranged at a center portion in each sector of a checkerboard pattern, or are regularly arranged in zigzags.

5. The method as claimed in claim 2, wherein the line type patterns or the dot type patterns have regular inter-pattern distances, irregular inter-pattern distances, or complex inter-pattern distances including regular and irregular inter-pattern distances.

6. The method as claimed in claim 1, wherein the transparent region has a size enough to prevent creation of nucleation.

7. The method as claimed in claim 1, wherein the laser beam has enough energy density to completely melt a portion of a film under the transparent region of maximum intensity, and to partially melt another portion of the film under the opaque region of minimum intensity, so as to form polycrystalline seed in the partially melted portion of the film.

8. The method as claimed in claim 1, wherein the laser beam has enough energy density to completely melts a portion of a film under the transparent region of maximum intensity, while near completely melts another portion of the film under the opaque region of minimum intensity, so that a single crystal seed remains in the near completely melted portion of the film.

9. The method as claimed in claim 1, wherein the laser beam has enough energy density to completely melt a portion of the film under the transparent region of maximum intensity, and to completely melt another portion of the film under the opaque region of minimum intensity.

10. The method as claimed in claim 1, wherein the film is any one film selected from a group of films, made of third group element, fifth group element, and their compound, which include an a-Si film, a poly-Si film, an a-Ge film, a poly-Ge film, an a-SiₓGe_{y} film, a poly-SiₓGe_{y} film, an a-GaNₓ film, a poly-GaNₓ film, an a-GaₓAs_{y} film, and a poly-GaₓAs_{y} film.

11. The method as claimed in claim 1, wherein the film is a metal film, or a compound film of metal and semiconductor.

12. The method as claimed in claim 11, wherein the metal film is any one film selected from a group of an Al film, a Cu film, a Ti film, a W film, an Au film, and a Ni film.
